(19) United States
(12) Patent Application Publication
(10) Pub. No.: US 2008/0160751 A1
(43) Pub. Date: Jul. 3, 2008

(54) MICROELECTRONIC DIE INCLUDING SOLDER CAPS ON BUMPING SITES THEREOF AND METHOD OF MAKING SAME

(76) Inventors: Mengzhi Pang, Phoenix, AZ (US); Charan Curumurthy, Higlez, AZ (US)

Correspondence Address: INTEL/BLAKELY, 1279 OAKMEAD PARKWAY, SUNNYVALE, CA, 94085-4040, US

(21) Appl. No.: 11/617,589

(22) Filed: Dec. 28, 2006

(51) Int. Cl. H01L 21/44

(52) U.S. Cl. 438/612

(57) ABSTRACT

A method of forming a microelectronic package, and a package formed according to the method. The method includes: providing a microelectronic substrate including bonding pads and solder bumps on respective ones of the bonding pads; providing a microelectronic die including bumping sites thereon; providing solder caps on the bumping sites; positioning the die onto the substrate to form a die-substrate combination, positioning including placing respective ones of the solder caps on the die in registration with corresponding ones of the solder bumps on the substrate; and bonding the die to the substrate by subjecting the die-substrate combination to reflow to form solder joints from the solder caps and solder bumps.

### FIELD

Embodiments of the present invention relate generally to methods of mounting a microelectronic die to a substrate, and to packages formed according to such methods.

### BACKGROUND

One of the well-known methods of mounting a microelectronic die or IC chip to a substrate includes flip-chip packaging. The substrate allows an encasing of the die while directing power and signal to and from the die. Flip chip packaging includes the use of an array of solder bumps attached to the bonding pads of the substrate in a process called “bumping.” The array of solder bumps is adapted to mate with discreet bumping sites on a receiving component, such as, for example, a die. By “bumping site,” what is meant in the context of the instant application is a site including one or more metallization layers on a bonding pad of a microelectronic component (such as, for example, a die or a substrate), the bumping site adapted to allow an electrical and mechanical joining of the microelectronic component with another microelectronic component, such as through a solder connection. An example of a bumping site as used herein would comprise the well known ENIG pad, including a barrier layer comprising for example a layer of Ni capped by a layer of Au. The package may be subsequently heated after mating of the die and substrate to partially liquefy or “reflow” the bumps, thus forming electrical and mechanical connections in the form of respective solder joints on respective ones of the bumping sites and land pads. This technology is frequently referred to as “flip chip” because the solder bumps are typically secured to the substrate wherein the die and associated bumping sites are then “flipped” to secure the die to the substrate.

In this regarding reference is made to FIGS. 1 and 2, which depict stages in the flip-chip mounting of a die to a substrate to form a microelectronic package. As seen in FIG. 1, a portion of a substrate 102 is shown including bonding pads 104 having solder bumps 106 formed thereon, including a low volume solder bump 106′. As is well known, low volume solder bumps such as bump 106′ may result from a number of events, such as, for example, solder mask lift off during the solder printing process onto the substrate. As further seen in FIG. 1, a portion of a die 108 is shown including bumping sites 110 thereon. Referring now to FIG. 2, a conventional flip-chip mounting process would involve placing respective substrate solder bumps 106 in registration and in contact with corresponding ones of the bumping sites 110, and exposing the thus formed assembly to elevated temperature in order to reflow the solder. During the reflow, the solder bumps 106/106′ in contact with the bumping sites 110 melt, forming melted solder portions 112. Disadvantageously, some of the melted solder portions 112 may be excessively wicked up by the corresponding bumping site 110, possibly creating the risk of the solder wicking open (SWO) as shown for example in the case of the solder portion 112′. In such a case, after solder solidification, no effective solder joint may be formed at the location of the SWO. Where a low volume solder bump, such as solder bump 106′, was present in a substrate bonding pad 104, such solder, as shown for example by solder portion 112″ may, after solidification, lead to the formation of a weak solder joint eventually possibly leading to solder joint cracking and electromigration. Another commonly observed LVSB related issue is that a solder joint may never form in the first place, leading to assembly failure.

The prior art fails to provide reliable methods of mounting a die to a substrate that do not exhibit problems typically associated with solder lift-up, such as, for example, missing solder joints, low volume solder joints, and solder joint cracking.

### BRIEF DESCRIPTION OF THE DRAWINGS

FIGS. 1 and 2 show stages in the flip-chip mounting of a die to a substrate according to the prior art; and

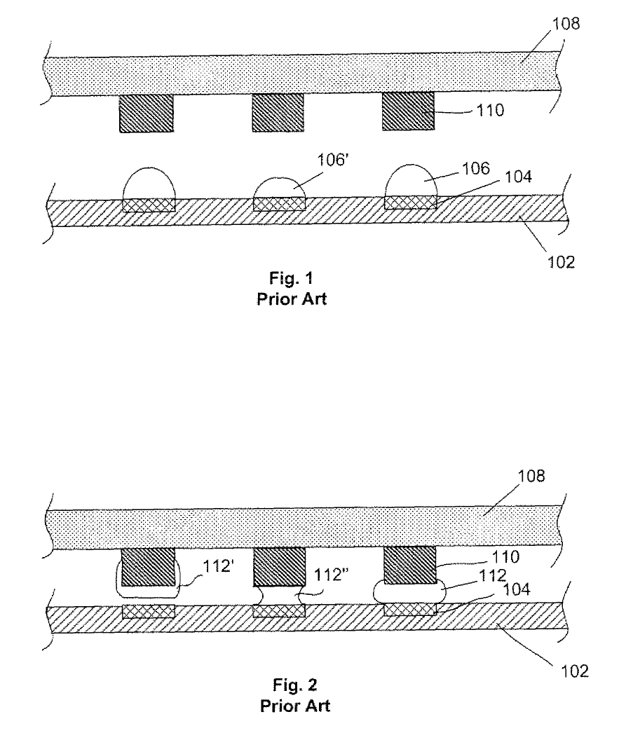

FIGS. 3-5 show stages in the flip-chip mounting of a die to a substrate according to an embodiment; and

FIG. 6 is a schematic view of a system including a package such as the package of FIG. 5.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a method of forming a microelectronic die, a microelectronic die formed according to the method, and a method of forming a microelectronic package including the die are disclosed. Reference is made to the accompanying drawings within, which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements.

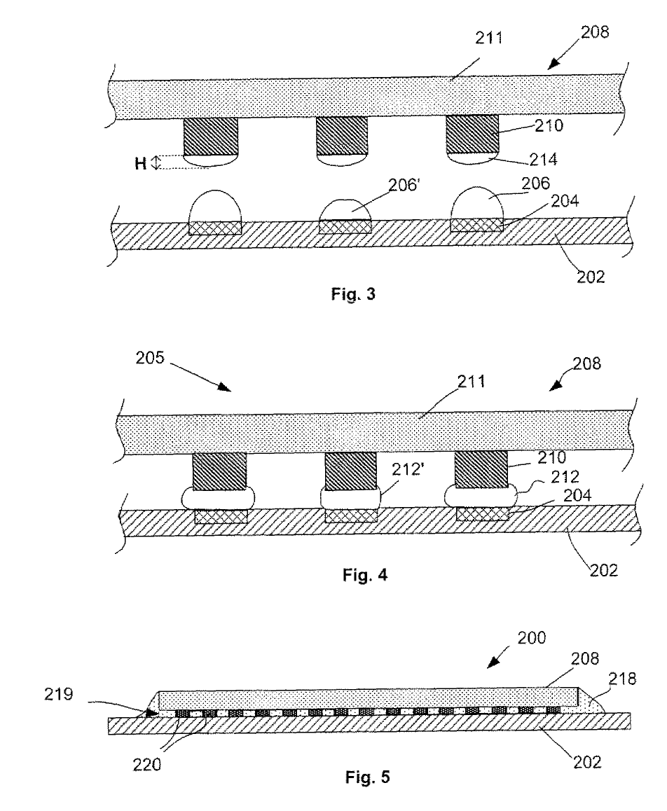

In one embodiment, a method of mounting a die to a substrate is disclosed. In another embodiment, a microelectronic package formed according to the method is disclosed. Aspects of this and other embodiments will be discussed herein with respect to FIGS. 3-6, below, where FIGS. 3-5 depict stages in the flip-chip mounting of a die to a substrate to form a microelectronic package. The figures, however, should not be taken to be limiting, as they are intended for the purpose of explanation and understanding.

Referring first to FIG. 3, a method embodiment of forming a microelectronic package includes providing a microelectronic substrate 202, a portion of which is shown in FIG. 3. By “microelectronic substrate,” what is meant in the context of the instant description is a substrate onto which microelectronic conductive patterns have been provided. The substrate may include either the substrate of a completed microelectronic device, or a substrate adapted to be further processed to form a microelectronic device, or a substrate, such as a printed wiring board, including conductive patterns adapted to provide interconnection between microelectronic components. For example the substrate can be an organic build-up substrate, a ceramic substrate, or a semiconductor substrate, such as a silicon substrate of a microelectronic die. The portion of substrate 202 is shown in FIG. 3 as including bonding pads 204 having solder bumps 206 formed thereon, including for example a low volume solder bump 206′. As mentioned previously, low volume solder bumps such as bump 206′ may result from a number of events, such as, for example, solder mask lift off during the solder printing process onto the substrate. LVAB may also be caused by solder reflow induced failure when excessive flux presence in the solder may disturb the solder wetting behavior and cause missing solder after de-fluxing. Another possible root cause of LVSB may be related to geometric irregularities of one or more recessed solder resist openings. In such a case, a solder resist opening larger than the nominal value may induce LVSB as a larger solder volume would be needed where in fact a smaller solder volume is provided. By showing a low volume solder bump 206′ as existing on the substrate 202, the instant description does not mean to suggest that the provision of a low volume solder bump 206′ is considered as being part of an embodiment, but rather to suggest that embodiments provide advantages for flip-chip mounting even in the presence of low volume solder bumps, such as solder bumps 206′, as will be described later in relation to FIGS. 4 and 5. The substrate bonding pads 204 may include any well known type of surface finish on the substrate, such as, for example, under bump metallization including layers of gold and nickel as would be within the knowledge of a person skilled in the art. It is noted that embodiments are not limited to the use of a substrate having bonding pads of a uniform size and pitch, as in the case of bonding pads 206, but include within their scope the provision of bonding pads of differing or non-uniform sizes and pitches. The substrate may further include a solder resist layer thereon (now shown), that is, as is well known, a heat-resisting coating material applied to specific areas on the surface of a substrate which may be provided mainly as a protective film for the conductive patterns of the substrate.

As further seen in FIG. 3, a method embodiment includes providing a microelectronic die, such as die 208, a portion of which is shown in FIG. 3. By “microelectronic die,” what is meant in the context of embodiments is a die substrate upon which microcircuits are formed, and which may include bumping sites as defined below. Examples of die substrates include, among others, wafers comprising silicon (Si), gallium arsenide (GaAs), Indium Phosphate (InP) and their derivations. Various techniques are used, such as layering, doping, masking, and etching, to build thousands and even millions of microscopic integrated circuit (IC) devices in the form of transistors, resistors, and others, as part of the die. The IC devices are interconnected to define a specific electronic circuit that performs a specific function, such as the function of a microprocessor or a computer memory. Referring now still to FIG. 3, the die substrate 211 includes bumping sites 210 thereon. The bumping sites 210 may include metallization layers as would be well known in the art, such as an electrically conductive layer including, for example, Cu, a stabilizing layer thereon, such as, for example, Au. Optionally, the bumping sites 210 may also include a barrier layer, such as, for example, a Ni layer on top of the Au layer, or any other metal layer according to application needs (not shown). The layers in the bumping sites 210 such as, for example, Cu layers, Ni layers and Au layers may be provided according to any one of well known methods, such as, for example, through electroless or electrolytic plating, as would be recognized by one skilled in the art.

Referring stilt to FIG. 3, a method embodiment further includes providing solder caps 214 onto the bumping sites 210. The solder caps 214 may be made of a compliant material, such as, for example, a Sn-based material, including, for instance, SnAg, SnCu or substantially pure Sn. The material for the solder caps would include most preferably Sn, and more preferably SnCu, and its selection would be a function of application needs. A “compliance” of the material of the solder caps may be expressed as their modulus of elasticity. Preferably, according to embodiments, where a number of different solder materials may be contemplated to be used as the material for the solder caps, a choice as to which of the solder materials would ultimately be used may be made based on which of those solder materials is the more compliant of the group, that is, as to which of those solder materials has the lowest modulus of elasticity of the group. A more compliant solder cap would help to reduce die stress and would therefore be a preferable choice. The solder caps may be provided according to any one of well known method for depositing solder, such as, for example, through electroplating the solder caps 214 onto the bumping sites 210. Other ways of providing the solder caps are within the purview of embodiments, such as, for example, printing, plating, ion/chemical/vapor deposition, dispensing, and placement. For example, the caps in the form of paste can be stencil printed or dispensed through a needle-type applicator onto the bumping sites. According to one embodiment, a height H would be at least about 10 microns. According to an embodiment, a volume of the solder caps 214 deposited onto the bumping sites 210 would be a function of minimum predetermined amount of solder (MPAS) to be used between the die and the substrate to bond the die the substrate. As would be recognized by one skilled in the art, the MPAS itself would be a function of the minimum required stand-off or minimum required gap (MRG) between the die and the substrate. The MRG, as is well known, is in turn is a function of a number of different factors including, for example, the bonding pads on the substrate. For instance, the pad diameter can determine how much solder needs to wet the pad surface, and then given the same solder volume deposited, a larger pad can results in a lower stand-off gap between die and substrate, whether or not an underfill material is contemplated for use between the die and the substrate, if applicable, the type of underfill material contemplated for use (such as, for example, capillary or no-flow), the thermal-mechanical resistance of the solder joints and the electromigration resistance of the solder joints. For example, where a capillary underfill material including a filler is contemplated for use, such as an underfill material including an epoxy resin having silica particles therein as the filler, a person skilled in the art would recognize the MRG as being about twice the maximum size of the filler particles in order to allow flow of the underfill material during a dispensing of the same between the die and substrate. At a minimum, the MRG according to an embodiment may be enough to establish a thermally, electrically and mechanically reliable solder joint between the die and substrate that would withstand thermal cycling and reliability stressing tests typically applied to the package, as would be recognized by one skilled in the art. An important factor to consider is the electromigration resistance of the solder joints when a substantially large current density is to be pumped through the solder joints during the operation of a CPU, for example. According to embodiments, larger solder volumes rather than smaller solder volumes are therefore preferred. According to one embodiment, providing solder caps may include providing each of the solder caps so that a combined volume of the solder cap being provided and of a corresponding one of the solder bumps is equal to or greater than the MPAS. In determining the above, however, it will be assumed that the volume of the corresponding one of the solder bumps does not correspond to a volume of a low volume solder bump, such as bump 206′, but rather to the volume of a solder bump contemplated for use on each of the bonding pads of the substrate.

Referring now to FIG. 4, a method embodiment includes positioning the die 208 onto the substrate 202 to form a die-substrate combination 205, and subjecting the die-substrate combination 205 to reflow temperatures, such as, for example, about 230 degrees Centigrade to about 260 degrees Centigrade to reflow the solder bumps 206 and solder caps 214 to form solder joints 220 (FIG. 5) therefrom. During the reflow, the solder bumps 206/206′ in contact with the solder caps 214 on the bumping sites 210 melt, forming melted solder portions 212, which include a combination of the solder bumps 206/206′ and solder caps 214. In particular, a combination of the bump 206′ with the corresponding solder cap results in solder portion 212′ as shown. An improved wettability of the solder caps with the solder bumps (as opposed to a wettability of the bumping sites with the solder bumps) brought about in part by a minimization of surface tension by virtue of the presence of the solder caps during the melting of the solder tends to merge the solder caps and the solder bumps much more readily than a merging of the bumping sites with the solder bumps according to the prior art. As suggested in FIG. 4 by solder portions 212, the preferential wetting between the solder caps 214 and the solder bumps 206/206′ tends to limit the extend of solder wicking to the bumping sites 210, and tends to at least partially compensate for low volume solder bumps such as bump 206′, thus decreasing the risk of solder wicking open, solder cracking, electromigration, or of low volume solder bump failure. In addition, the presence of the solder caps 214 would result in taller solder joints and therefore in a larger gap height between the die 208 and the substrate 202 than would be achieved with the solder bumps 206/206′ alone. As a result, more compliant solder joints would result, as a taller solder joint will have more ability to absorb stress and would therefore be considered to be more compliant than its shorter counterpart, indicating better solder joint reliability and performance with respect to electromigration resistance. The electromigration resistance, as is well known, refers to the number of hours the solder joint will be still electrically functional under electrical current. A solidification of the melted solder caps 214 and solder bumps 206/206′ as a result of reflow would yield solder joints 220 as shown in FIG. 5.

Referring now to FIG. 5, a method embodiment includes providing an underfill material 218 between the die 208 and the substrate 202. Underfill material 218 may be provided and cured within the gap 219 between the microelectronic die 208 and the carrier substrate 202, the gap surrounding the solder joints 220 formed from a reflow of the solder caps 214 and solder bumps 206/206′. The process of applying underfill material 218 to the gap 219 as shown in FIG. 5 is according to a capillary underfill regime as is well known in the art. However, embodiments are not limited to the use of an underfill material, or to the use of a capillary underfill regime as shown in the figures, but rather include within their scope, among others, a package where no underfill is used in the gap 219 between die 208 and substrate 202 and a package where a no-flow underfill is used in the gap 219 between the die 208 and substrate 202. An underfill material, such as underfill material 218, after cure, helps to prevent loading on the solder joints 220 during thermal cycling by supporting the microelectronic die 208 and the carrier substrate 202.

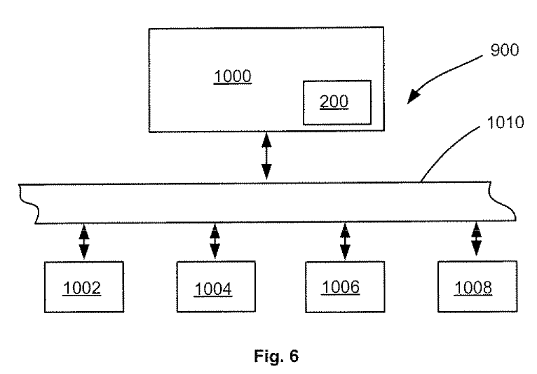

Referring to FIG. 6, there is illustrated one of many possible systems 900 in which embodiments of the present invention may be used. In one embodiment, the electronic assembly 1000 may include a microelectronic package, such as package 200 of FIG. 4. Assembly 1000 may further include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 6, the system 900 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

The various embodiments described above have been presented by way of example and not by way of limitation. Having thus described in detail embodiments of the present invention, it is understood that the invention defined by the appended claims is not to be limited by particular details set forth in the above description, as many variations thereof are possible without departing from the spirit or scope thereof.

What is claimed is:

1. A method of providing a microelectronic die comprising:
providing a die substrate;
providing bumping sites on a surface of the substrate; and
providing solder caps on the bumping sites.

2. The method of claim 1, wherein providing solder caps comprises:
selecting a group of differing solder materials for the solder caps;
choosing a solder material from the group having a lowest modulus of elasticity among the group.

3. The method of claim 1 wherein the solder caps comprise Sn.

4. The method of claim 3, wherein the solder caps comprise one of SnAg, SnCu and substantially pure Sn.

5. The method of claim 1, wherein providing solder caps comprises electroplating the solder caps onto the bumping sites.

6. The method of claim 1, wherein the solder caps have a height of at least about 10 microns.

7. A method of forming a microelectronic package, comprising:
providing a microelectronic substrate including bonding pads and solder bumps on respective ones of the bonding pads;
providing a microelectronic die including bumping sites thereon;
providing solder caps on the bumping sites;
positioning the die onto the substrate to form a die-substrate combination, positioning including placing respective ones of the solder caps on the die in registration with corresponding ones of the solder bumps on the substrate,
bonding the die to the substrate by subjecting the die-substrate combination to reflow to form solder joints from the solder caps and solder bumps.

8. The method of claim 7, wherein providing solder caps comprises:
selecting a group of differing solder materials for the solder caps;
choosing a solder material from the group having a lowest modulus of elasticity among the group.

9. The method of claim 7, wherein the solder caps comprise Sn.

10. The method of claim 9, wherein the solder caps comprise one of SnAg, SnCu and substantially pure Sn.

11. The method of claim 7, wherein providing solder caps comprises electroplating the solder caps onto the bumping sites.

12. The method of claim 7, wherein the solder caps have a height of at least about 10 microns.

13. The method of claim 7, wherein providing solder caps comprises providing each of the solder caps to have a volume such that a combined volume of each of the solder caps with a corresponding one of the solder bumps is equal to or greater than a minimum predetermined volume of solder to be used between the die and the substrate.

14. A microelectronic die including:
a die substrate;
a plurality of bumping sites on the die substrate;
a plurality of solder caps on respective ones of the bumping sites.

15. The die of claim 14, wherein the solder caps comprise Sn.

16. The die of claim 14, wherein the solder caps comprise one of SnAg, SnCu and substantially pure Sn.

17. The die of claim 14, wherein the solder caps have a height greater than or equal to 10 microns.
